(19) United States
(12) Patent Application Publication
(10) Pub. No.: US 2024/0379629 A1
(43) Pub. Date: Nov. 14, 2024

(54) DISPLAY PANEL

(71) Applicant: AUO Corporation, Hsinchu (TW)

(72) Inventors: Sheng-Chin Wang, Hsinchu (TW); Kuan-Hsun Chen, Hsinchu (TW)

(73) Assignee: AUO Corporation, Hsinchu (TW)

(21) Appl. No.: 18/544,436

(22) Filed: Dec. 19, 2023

(30) Foreign Application Priority Data
May 12, 2023 (TW) 112117679

(51) Int. Cl. H01L 25/075; H01L 33/44; H01L 33/52; H01L 33/58

(52) U.S. Cl. CPC H01L 25/0753; H01L 33/44; H01L 33/52; H01L 33/58

(57) ABSTRACT

A display panel including a substrate, multiple display units, an encapsulation layer, and a block strip is disclosed. The display units are disposed over the substrate. The encapsulation layer is disposed over the substrate and between the display units. The block strip is disposed between the encapsulation layer and the substrate, and extends along an edge of the substrate.

### CROSS-REFERENCE TO RELATED APPLICATION

This application claims the priority benefit of Taiwan application serial no. 112117679, filed on May 12, 2023. The entirety of the above-mentioned patent application is hereby incorporated by reference herein and made a part of this specification.

### BACKGROUND

### Technical Field

This disclosure relates to a light-emitting panel, and particularly relates to a display panel.

### Description of Related Art

Micro-LED displays have the advantages of power saving, high efficiency, high brightness, and fast response time. Due to the extremely small size of micro-LEDs, a current method of manufacturing the micro-LED display is to use a mass transfer technology to transfer a large number of micro-LED dies to a glass substrate all at once. However, since a yield of the mass transfer technology still needs to be improved, a current approach is to first manufacture small-sized display panels and then splice the display panels into a large-sized display.

In order to achieve seamless splicing, the glass substrate and encapsulant of the display panel need to be cut separately so that the display panel has a predetermined size. In order to further simplify the manufacturing process, laser cutting is currently used to cut the glass substrate and encapsulant simultaneously. However, due to the difference in cutting energy required by the glass substrate and the encapsulant, a thermal impact range of the laser cutting on the encapsulant is too large, and the encapsulant may retract from an edge of the glass substrate after absorbing too much heat, causing thin encapsulant or lack of glue at the edge of the display panel, and causing a problem of light leakage at the edge of the display panel, and even obvious tiling lines in the spliced display, which affects the display quality.

### SUMMARY

The disclosure is directed to a display panel, which is adapted to mitigate a problem of edge light leakage.

An embodiment of the disclosure provides a display panel including a substrate, multiple display units, an encapsulation layer, and a block strip. The display units are disposed over the substrate. The encapsulation layer is disposed over the substrate and between the display units. The block strip is disposed between the encapsulation layer and the substrate, and extends along an edge of the substrate.

In an embodiment of the disclosure, the block strip extends continuously on three side edges of the substrate.

In an embodiment of the disclosure, the block strip and scan lines of the display panel belong to a same film layer.

In an embodiment of the disclosure, the block strip is electrically floating.

In an embodiment of the disclosure, an absorption rate of the block strip to infrared laser is less than 0.1%.

In an embodiment of the disclosure, the block strip includes metal.

In an embodiment of the disclosure, a side surface of the substrate, a side surface of the block strip, and a side surface of the encapsulation layer are substantially aligned with each other.

In an embodiment of the disclosure, the display panel further includes a sealing layer covering the side surface of the substrate, the side surface of the block strip, and the side surface of the encapsulation layer.

In an embodiment of the disclosure, cutting marks extend continuously on the side surface of the substrate, the side surface of the block strip, and the side surface of the encapsulation layer.

In an embodiment of the disclosure, when a light transmittance of the encapsulation layer is greater than or equal to 80%, the display panel further includes an anti-reflective layer, and the anti-reflective layer is sandwiched between the encapsulation layer and the block strip. In an embodiment of the disclosure, a width of the block strip is 50 μm to 100 μm.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic top view of a display panel 10 according to an embodiment of the disclosure.

FIG. 1B is a schematic cross-sectional view along a section line A-A′ in FIG. 1A.

FIG. 2 is a partial cross-sectional view of a display panel 20 according to an embodiment of the disclosure.

### DESCRIPTION OF THE EMBODIMENTS

In the drawings, the thickness of layers, films, panels, regions, etc., are exaggerated for clarity's sake. It will be understood that when a component such as a layer, a film, a region, or a substrate is referred to be “on” or “connected to” another component, it may be directly on or connected to the other another component, or intermediate components may also exist there between. Comparatively, when a component is referred to be “directly on” or “directly connected” to another, none other intermediate component exits there between. As used herein, the “connection” may refer to physical and/or electrical connection. Furthermore, “electrical connection” or “coupling” of two components may refer to that other components may exist between the two components.

It should be noted that although the terms “first”, “second”, “third”, etc. may be used for describing various elements, components, regions, layers and/or portions, the elements, components, regions, layers and/or portions are not limited by these terms. These terms are only used for separating one element, component, region, layer or portion from another element, component, region, layer, or portion. Therefore, the following discussed first “element”, “component”, “region”, “layer” or “portion” may be referred to as the second element, component, region, layer, or portion without departing from the scope of the disclosure.

The terminology used herein is for the purpose of describing particular embodiments and is not intended to be limiting of the disclosure. As used herein, the singular forms “a,” “an” and “the” are intended to include the plural forms as well, unless the context clearly indicates otherwise. “or” represents “and/or”. The term “and/or” used herein includes any or a combination of one or more of the associated listed items. It will be further understood that the terms “comprises,” “comprising,” “includes” and/or “including,” when used herein, specify the presence of stated features, regions, integers, steps, operations, elements, and/or components, but do not preclude the presence or addition of one or more other features, regions, integers, steps, operations, elements, components, and/or groups thereof.

Moreover, relative terms such as “under” or “bottom” and “above” or “top” may be used for describing a relationship of one element and another element as that shown in figures. It should be noted that the relative terms are intended to include a different orientation of the device besides the orientation shown in the figure. For example, if a device in a figure is flipped over, the element originally described to be located “under” other element is oriented to be located “above” the other element. Therefore, the illustrative term “under” may include orientations of “under” and “on”, which is determined by the specific orientation of the figure. Similarly, if a device in a figure is flipped over, the element originally described to be located “below” or “underneath” other element is oriented to be located “on” the other element. Therefore, the illustrative term “under” or “below” may include orientations of “above” and “under”.

Considering a specific amount of measurement and measurement related errors discussed (i.e., limitations of a measurement system), the terms “about”, “substantial” or “approximate” used herein include the related value and an average within an acceptable deviation range for a specific value determined by those skilled in the art, considering a discussed measurement and a specific number of errors related to the measurement (i.e., a limitation of a measuring system). For example, “about” may represent a range within one or a plurality of standard deviations of the related value, or within +30%, +20%, +10%, +5%. Moreover, the “about”, “substantially”, or “approximate” used herein may be a more acceptable deviation range or standard deviation based on optical properties, etching properties, or other properties, and not one standard deviation may be applied to all properties.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The exemplary embodiment is described below with reference of a cross-sectional view of a schematic diagram of an idealized embodiment. Therefore, a shape change of the figure serving as a result of manufacturing techniques and/or tolerances may be expected. Therefore, the embodiment of the disclosure should not be construed as limited to a particular shape of a region as shown herein, but includes a shape deviation caused by manufacturing tolerance. For example, a shown or described flat area may generally have rough and/or non-linear features. Moreover, a shown acute angle may be round. Therefore, a region shown in the figure is essentially schematic, and a shape thereof is not intended to show an accurate shape of the region, and is not intended to limit a range of the claims of the disclosure.

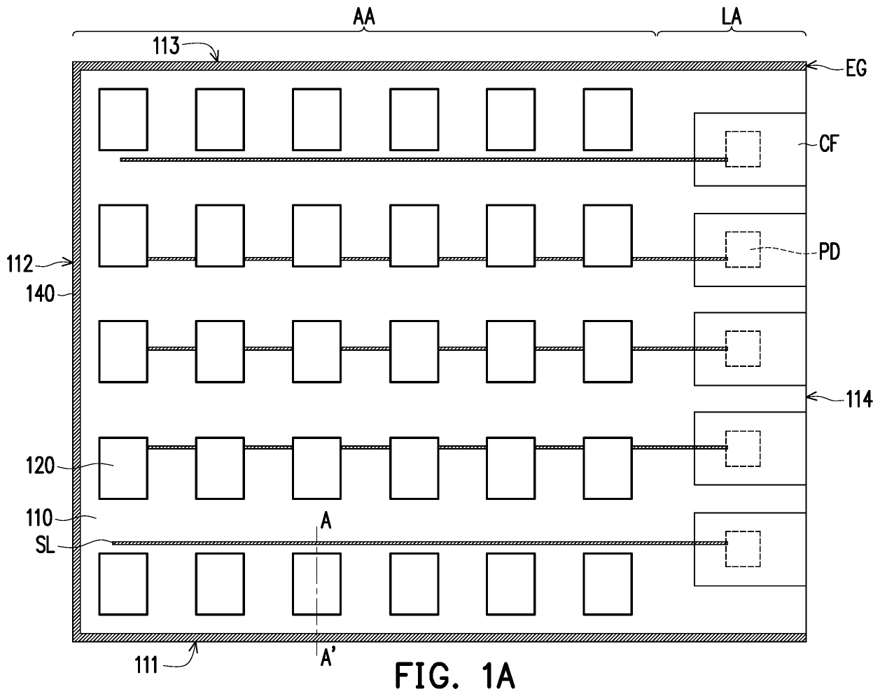

FIG. 1A is a schematic top view of a display panel 10 according to an embodiment of the disclosure. FIG. 1B is a schematic cross-sectional view along a section line A-A′ in FIG. 1A. In order to simplify an expression of the figures, FIG. 1A schematically illustrates a substrate 110, display units 120 and a block strip 140, and some components are omitted.

Referring to FIG. 1A and FIG. 1B, a display panel 10 includes: the substrate 110, the plurality of display units 120, an encapsulation layer 130 and the block strip 140. The plurality of display units 120 are disposed over the substrate 110. The encapsulation layer 130 is located over the substrate 110 and between the plurality of display units 120. The block strip 140 is located between the encapsulation layer 130 and the substrate 110 and extends along an edge EG of the substrate 110.

In the display panel 10 according to an embodiment of the disclosure, the block strip 140 is used to prevent excessive heat from transferring to the encapsulation layer 130 during a cutting process, and may effectively maintain an edge thickness of the encapsulation layer 130, so as to avoid a problem of edge light leakage of the display panel 10.

With reference to FIG. 1A and FIG. 1B, implementation of each component of the display panel 10 will be described below, but the disclosure is not limited thereto.

In some embodiments, the substrate 110 of the display panel 10 may be a circuit substrate. For example, the substrate 110 may include components or circuits required by the display panel 10, such as driving components, switch components, storage capacitors, power lines, driving signal lines, timing signal lines, current compensation lines, detection signal lines, and so on. In some embodiments, the substrate 110 includes a switch element array. In some embodiments, the substrate 110 has a top surface 110T and a bottom surface 110B opposite to each other and a side surface 110E, and the side surface 110E connects the top surface 110T and the bottom surface 110B.

In some embodiments, the display panel 10 may have a display area AA and an external pin wiring area LA. In some embodiments, the external pin wiring area LA is located on one side of the display area AA. In some embodiments, the substrate 110 includes a plurality of pads PD for electrically connecting the substrate 110 to the outside. In some embodiments, the pads PD are disposed in the display area AA and the external pin wiring area LA. In some embodiments, the pads PD are disposed on the top surface 110T of the substrate 110, but the disclosure is not limited thereto. In some embodiments, the display panel 10 further includes a chip bonding film CF, and the chip bonding film CF is electrically connected to the pads PD. In some embodiments, pins of the chip bonding film CF are electrically connected to the pads PD through a conductive glue (for example, an anisotropic conductive glue).

In some embodiments, the plurality of display units 120 are disposed on the top surface 110T of the substrate 110, and the plurality of display units 120 are only disposed in the display area AA, and the display units 120 are not disposed in the external pin wiring area LA. The plurality of display units 120 may be arranged on the substrate 110 in a regular or irregular form as needed. In some embodiments, the plurality of display units 120 may be arranged on the substrate 110 in an array. In some embodiments, the display unit 120 may include a light-emitting diode, such as a micro light-emitting diode (micro-LED) or an organic LED (OLED). In some embodiments, each display unit 120 may include one LED, but the disclosure is not limited thereto. In some embodiments, each display unit 120 may include a plurality of LEDs. In some embodiments, the display unit 120 may be electrically connected to the substrate 110 or other components disposed on the substrate 110, such as the chip bonding film CF or a driving chip, through the pads PD on the substrate 110.

In some embodiments, the encapsulation layer 130 is disposed in the display area AA, and the encapsulation layer 130 is located on the top surface 110T of the substrate 110 and between the plurality of display units 120. In some embodiments, the encapsulation layer 130 is only provided in the display area AA. In some embodiments, the encapsulation layer 130 further extends to the external pin wiring area LA. In some embodiments, the display panel 10 is an opaque display panel, and the encapsulation layer 130 includes an anti-reflective material, such as a black light-absorbing material. Therefore, the encapsulation layer 130 should expose at least a light-emitting surface of the display unit 120. For example, a level of a top surface 130T of the encapsulation layer 130 may be lower than a level of a top surface 120T of the display unit 120, but the disclosure is not limited thereto. In some embodiments, the level of the top surface 130T of the encapsulation layer 130 may be substantially equal to the level of the top surface 120T of the display unit 120. In some embodiments, when a thickness of the encapsulation layer 130 is about 5 μm to 10 μm, an optical density (OD) or a blackout value of the encapsulation layer 130 is greater than or equal to 3. In some embodiments, the encapsulation layer 130 includes a thermosetting glue.

The block strip 140 may continuously extend on the top surface 110T of the substrate 110 along a predetermined cutting route. For example, when a laser is used to cut a first side 111, a second side 112 and a third side 113 of the substrate 110 and the encapsulation layer 130 from the bottom surface 110B of the substrate 110, the block strip 140 may be disposed on the cutting route of the first side 111, the second side 112 and the third side 113 of the substrate 110, and the block strip 140 is located between the top surface 110T of the substrate 110 and the encapsulation layer 130. In this way, during the cutting process, the block strip 140 may reduce a laser heat transferred to the encapsulation layer 130, so that the heat transferred to the encapsulation layer 130 is only enough to break bonds of molecules in the encapsulation layer 130, but will not be excessive to cause retraction of the encapsulation layer 130. In other words, the block strip 140 may help adjusting the heat transferred to the encapsulation layer 130, thereby preventing the encapsulation layer 130 from retracting and having insufficient thickness due to excessive heat absorption.

In some embodiments, the above-mentioned cutting may be implemented by using infrared (IR) laser, ultraviolet (UV) laser or other suitable cutting tools. In some embodiments, an absorption rate of the block strip 140 to the IR laser is less than 0.1%. In some embodiments, a wavelength of the IR laser is between 750 nm and 1400 nm, such as 1064 nm. In some embodiments, a material of the block strip 140 includes metal, such as gold (Au), copper (Cu) or silver (Ag). The block strip 140 may belong to a same film layer as any conductive layer under the display unit 120. In some embodiments, the block strip 140 and scan lines SL of the display panel 10 belong to the same film layer, but the disclosure is not limited thereto. In other embodiments, the block strip 140 and data lines or common electrode lines of the display panel belong to the same film layer. In some embodiments, the block strip 140 is electrically floating.

After the cutting operation is completed, the block strip 140 may continuously extend on the three side edges of the first side 111, the second side 112 and the third side 113 of the substrate 110, and the side surface 110E of the substrate 110 may be substantially aligned with the side surface 140E of the block strip 140. In some embodiments, the side surface 140E of the block strip 140 is further substantially aligned with the side surface 130E of the encapsulation layer 130. In some embodiments, the side surface 130E of the encapsulation layer 130, the side surface 140E of the block strip 140, and the side surface 110E of the substrate 110 are substantially aligned with each other. In some embodiments, cutting marks formed by the cutting operation continuously extend on the side surface 110E of the substrate 110, the side surface 140E of the block strip 140, and the side surface 130E of the encapsulation layer 130.

In some embodiments, the display panel 10 does not have the external pin wiring area LA, and the cutting operation may be performed to the first side 111, the second side 112, the third side 113 and a fourth side 114 of the substrate 110 and the encapsulation layer 130, so that the block strip 140 continuously extends to the four edges of the first side 111, the second side 112, the third side 113 and the fourth side 114 of the substrate 110 after the cutting operation is completed. In some embodiments, other insulating layers and/or conductive layers may also be provided on the block strip 140.

A width design of the block strip 140 may take into account a light spot size of laser light and cutting accuracy of the cutting operation. In some embodiments, a width W1 of the block strip 140 may be a sum of the light spot size of the laser light and a cutting accuracy range. For example, if the light spot size of the laser light is 5 μm and the cutting accuracy of the cutting operation is +20 μm, the width W1 of the block strip 140 may be approximately 45 μm to 50 μm. In some embodiments, the width W1 of the block strip 140 is approximately 40 μm to 100 μm, such as 55 μm, 70 μm, or 85 μm.

A thickness design of the block strip 140 may be adjusted by considering an intensity of an energy source used in the cutting operation and/or a difference between energy required to cut the substrate 110 and energy required to cut the encapsulation layer 130. In some embodiments, a thickness TH of the block strip 140 is proportional to a laser power used in the cutting operation. In some embodiments, the thickness TH of the strip barrier layer 140 is proportional to the difference between the energy required to cut the substrate 110 and the energy required to cut the encapsulation layer 130. In some embodiments, the thickness TH of the block strip 140 is 600 nm to 1200 nm, such as 700 nm, 850 nm or 1000 nm.

In some embodiments, the display panel 10 further includes an optical layer 150, and the optical layer 150 is located on the plurality of display units 120 and the encapsulation layer 130. In some embodiments, the optical layer 150 is only provided in the display area AA. In some embodiments, a side surface 150E of the optical layer 150 extends beyond the side surface 130E of the encapsulation layer 130. In some embodiments, the optical layer 150 includes a plurality of film layers, such as polarizers, anti-glare films, anti-reflective films, or other suitable optical films. In some embodiments, the optical layer 150 further includes an adhesive layer 151, such as silicone or polyurethane reactive adhesive, and the optical layer 150 may be fixed on the display units 120 and the encapsulation layer 130 through the adhesive layer 151.

In some embodiments, the display panel 10 further includes a sealing layer 160, and the sealing layer 160 covers the side surface 110E of the substrate 110, the side surface 140E of the block strip 140, and the side surface 130E of the encapsulation layer 130. In some embodiments, the optical layer 150 is located on the sealing layer 160, and the sealing layer 160 may physically contact the side surface 130E of the encapsulation layer 130 and a bottom surface 150B of the optical layer 150, so as to seal an interface between the encapsulation layer 130 and the optical layer 150 to avoid the interface between the encapsulation layer 130 and the optical layer 150 from peeling off due to a high temperature and high humidity environment, thereby improving the reliability of the display panel 10. In some embodiments, the top surface 130T of the encapsulation layer 130 is aligned with a top surface 160T of the sealing layer 160. In some embodiments, the cutting operation may be further performed to the optical layer 150 and the sealing layer 160, and after the cutting operation is completed, cutting marks on the side surface 150E of the optical layer 150 may continuously extend to a side surface 160E of the sealing layer 160. In some embodiments, the sealing layer 160 includes at least one of polyurethane acrylate (PUA), epoxy acrylate, and silicone, but the disclosure is not limited thereto.

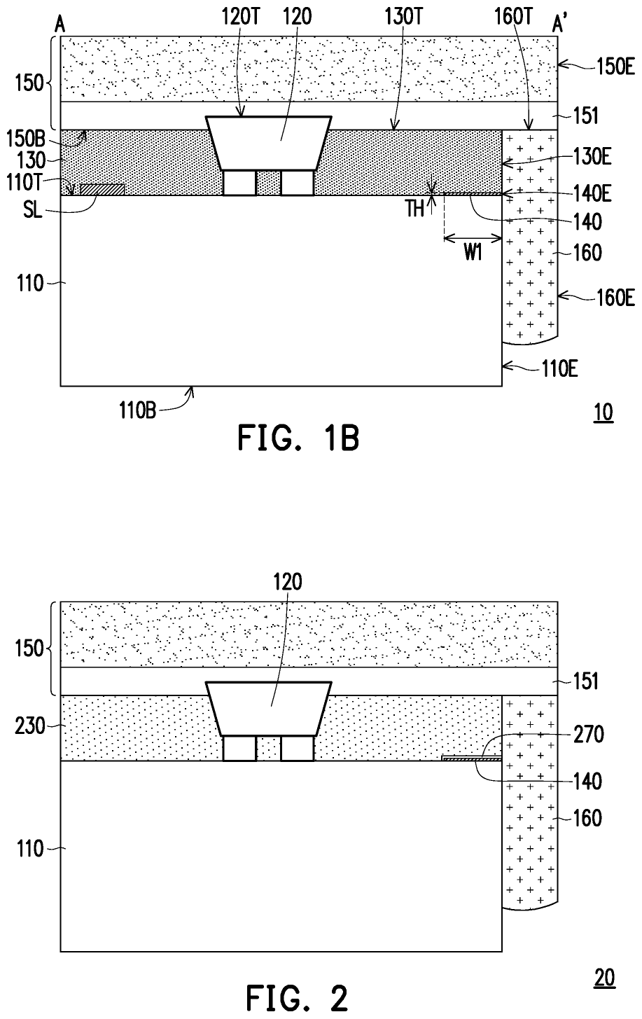

In the following description, FIG. 2 is used to continue to describe other embodiments of the disclosure, and the component numbers and related content of the embodiment of FIG. 1A to FIG. 1B are still used, where the same numbers are used to represent the same or similar elements, and explanations of the same technical content are omitted. For descriptions of omitted parts, reference may be made to the embodiments of FIG. 1A to FIG. 1B, which will not be repeated in the following description.

FIG. 2 is a partial cross-sectional view of a display panel 20 according to an embodiment of the disclosure. The display panel 20 may include a substrate 110, a plurality of display units 120, an encapsulation layer 230, a block strip 140, an optical layer 150 and a sealing layer 160. Compared with the display panel 10 shown in FIG. 1A and FIG. 1B, the display panel shown in FIG. 2A and FIG. 2B is mainly different in that: the display panel 20 may be a transparent display panel, the encapsulation layer 230 may include a transparent encapsulation adhesive, and the display panel 20 may further include an anti-reflective layer 270. The anti-reflective layer 270 may be sandwiched between the encapsulation layer 230 and the block strip 140 to prevent light from being reflected by the block strip 140 to affect the display quality of the display panel 20.

In some embodiments, a material of the anti-reflective layer 270 is non-metal. For example, the anti-reflective layer 270 may include oxide. In some embodiments, a light transmittance of the encapsulation layer 230 is greater than or equal to 80%. In some embodiments, the anti-reflective layer 270 completely covers the block strip 140.

In summary, the display panel of the disclosure uses a block strip to reduce the heat transferred to the encapsulation layer during the cutting process, which may prevent the encapsulant from retracting from the edge of the substrate, thereby preventing the edge of the display panel from being thin or lacking in adhesive. In this way, the problem of edge light leakage of the display panel may be avoided, thereby preventing tiling line defects in a display made of spliced display panels, and improving the display quality and production yield of the spliced display.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A display panel, comprising:
a substrate;
a plurality of display units, disposed over the substrate;
an encapsulation layer, disposed over the substrate and between the plurality of display units; and
a block strip, disposed between the encapsulation layer and the substrate, and extending along an edge of the substrate.

2. The display panel according to claim 1, wherein the block strip extends continuously on three side edges of the substrate.

3. The display panel according to claim 1, wherein the block strip and scan lines of the display panel belong to a same film layer.

4. The display panel according to claim 1, wherein the block strip is electrically floating.

5. The display panel according to claim 1, wherein an absorption rate of the block strip to infrared laser is less than 0.1%.

6. The display panel according to claim 1, wherein the block strip comprises metal.

7. The display panel according to claim 1, wherein a side surface of the substrate, a side surface of the block strip, and a side surface of the encapsulation layer are substantially aligned with each other.

8. The display panel according to claim 7 further comprising: a sealing layer covering the side surface of the substrate, the side surface of the block strip, and the side surface of the encapsulation layer.

9. The display panel according to claim 1, wherein cutting marks extend continuously on the side surface of the substrate, the side surface of the block strip, and the side surface of the encapsulation layer.

10. The display panel according to claim 1, wherein when a light transmittance of the encapsulation layer is greater than or equal to 80%, the display panel further comprises an anti-reflective layer, and the anti-reflective layer is sandwiched between the encapsulation layer and the block strip.

11. The display panel according to claim 1, wherein a width of the block strip is 50 μm to 100 μm.
